(19) United States
(12) Patent Application Publication
(10) Pub. No.: US 2025/0240968 A1
(43) Pub. Date: Jul. 24, 2025

(54) SEMICONDUCTOR DEVICE AND ELECTRONIC SYSTEM INCLUDING SEMICONDUCTOR DEVICE

(71) Applicant: SAMSUNG ELECTRONICS CO., LTD., SUWON-SI (KR)

(72) Inventors: SANGEUN LEE, Suwon-si (KR); CHANHO LEE, Suwon-si (KR); SUKKANG SUNG, Suwon-si (KR); CHEON AN LEE, Suwon-si (KR)

(21) Appl. No.: 18/977,485

(22) Filed: Dec. 11, 2024

(30) Foreign Application Priority Data
Jan. 19, 2024 (KR) 10-2024-0009096

(51) Int. Cl. H10B 43/40; H10B 41/41

(52) U.S. Cl. CPC H10B 43/40; H10B 41/41

(57) ABSTRACT

A semiconductor device includes a semiconductor substrate that includes a first transistor region and a second transistor region, a plurality of transistors that include a first transistor located in the first transistor region and a second transistor located in the second transistor region and that has a greater operating voltage than the first transistor, and a first metal layer disposed on the first transistor and the second transistor. The first metal layer overlaps the second transistor and does not overlap a neighboring second transistor, and the first metal layer overlaps the first transistor and includes a wire that overlaps a neighboring first transistor.

### CROSS-REFERENCE TO RELATED APPLICATION

This application claims priority under 35 U.S.C. 119 from Korean Patent Application No. 10-2024-0009096, filed in the Korean Intellectual Property Office on Jan. 19, 2024, the contents of which are herein incorporated by reference in their entirety.

### TECHNICAL FIELD

Embodiments of the present disclosure are directed to a semiconductor device and an electronic system that includes the semiconductor device.

### DISCUSSION OF THE RELATED ART

Semiconductor devices are widely used in various electronic industries because they can be miniaturized and perform various functions. Technologies that can improve the performance of semiconductor devices and their integration are the subject of research. For example, the degree of integration of a semiconductor device can be improved by reducing the size of a plurality of circuit elements in the semiconductor device.

### SUMMARY

Embodiments of the present disclosure provide a semiconductor device and an electronic system that includes the same that improves performance and integration.

An embodiment of the disclosure provides a semiconductor device that includes a semiconductor substrate that includes a first transistor region and a second transistor region, a plurality of transistors that includes a first transistor located in the first transistor region and a second transistor located in the second transistor region and that has a greater operating voltage than the first transistor, a first metal layer disposed on the first transistor and the second transistor. The first metal layer overlaps the second transistor but does not overlap a neighboring second transistor, and the first metal layer overlaps the first transistor and includes a wire that overlaps a neighboring first transistor.

Another embodiment of the disclosure provides a semiconductor device that includes a semiconductor substrate that includes a first transistor region and a second transistor region, a plurality of transistors that include a first transistor located in the first transistor region and a second transistor located in the second transistor region and that has a greater operating voltage than the first transistor, a first metal layer disposed on the second transistor, and a second metal layer disposed on the first metal layer. The first metal layer overlaps the second transistor and does not overlap a neighboring second transistor, and the second metal layer overlaps the second transistor and includes a wire that overlaps a neighboring second transistor.

Another embodiment of the disclosure provides an electronic system that includes a main substrate, a semiconductor device disposed on the main substrate, and a controller electrically connected to the semiconductor device on the main substrate. The semiconductor device includes a semiconductor substrate that includes a first transistor region and a second transistor region, a plurality of transistors that include a first transistor located in the first transistor region and a second transistor located in the second transistor region and that has a greater operating voltage than the first transistor, and a first metal layer disposed on the first transistor and the second transistor. The first metal layer overlaps the second transistor and does not overlap a neighboring second transistor, and the first metal layer overlaps the first transistor and includes a wire that overlaps a neighboring first transistor.

According to an embodiment, a semiconductor device and an electronic system that includes the same can improve performance and integration.

### BRIEF DESCRIPTION OF THE DRAWINGS

FIG. 1 is a cross-sectional view of a semiconductor device according to an embodiment.

FIG. 2 is an enlarged cross-sectional view of a channel structure in a semiconductor device shown in FIG. 1.

FIG. 3 and FIG. 4 are enlarged top plan views of a portion of a semiconductor device shown in FIG. 1.

FIG. 5 is a plan view of an arrangement of a second transistor according to an embodiment.

FIG. 6 is a cross-sectional view taken along line I-I′ of FIG. 5.

FIG. 7 is a plan view of an arrangement of a first transistor according to an embodiment.

FIG. 8 is a cross-sectional view taken along line II-II' of FIG. 5.

FIG. 9 shows the same cross-section as FIG. 5, with respect to a semiconductor device according to another embodiment.

FIG. 10 shows the same cross-section as FIG. 7, with respect to a semiconductor device according to another embodiment.

FIG. 11 is a cross-sectional view of a semiconductor device 20 according to an additional embodiment.

FIG. 12 schematically shows an electronic system that includes a semiconductor device according to an embodiment.

FIG. 13 is a perspective view of an electronic system that includes a semiconductor device according to an embodiment.

FIG. 14 and FIG. 15 are cross-sectional views of a semiconductor package according to embodiment.

### DETAILED DESCRIPTION

Embodiments of the present disclosure will be described more fully hereinafter with reference to the accompanying drawings, in which embodiments of the disclosure are shown. As those skilled in the art would realize, described embodiments can be modified in various different ways, all without departing from the spirit or scope of the present disclosure.

Like reference numerals may designate like elements throughout the specification. It will be understood that when an element such as a layer, film, region, area or substrate is referred to as being “on” or “above” another element, it can be directly on the other element or intervening elements may also be present.

Hereinafter, a semiconductor device according to an embodiment and electronic system will be described in detail with reference to the drawings.

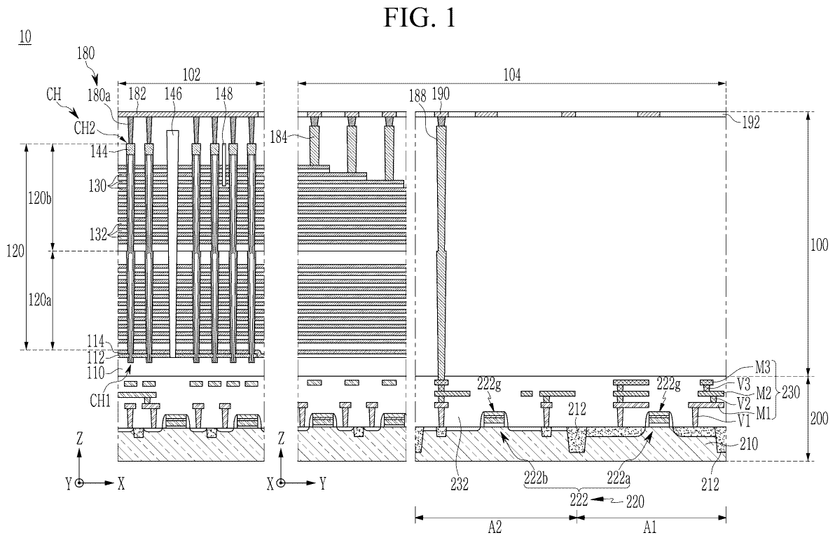

Hereinafter, referring to FIG. 1 to FIG. 4, a semiconductor device and a manufacturing method thereof according to an embodiment will be described in detail.

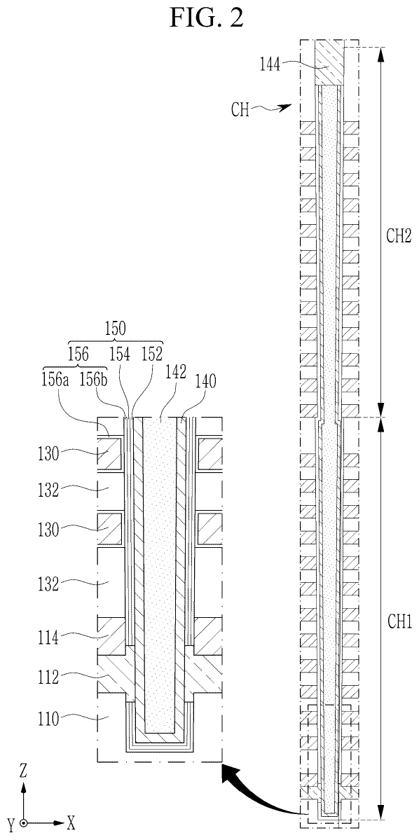

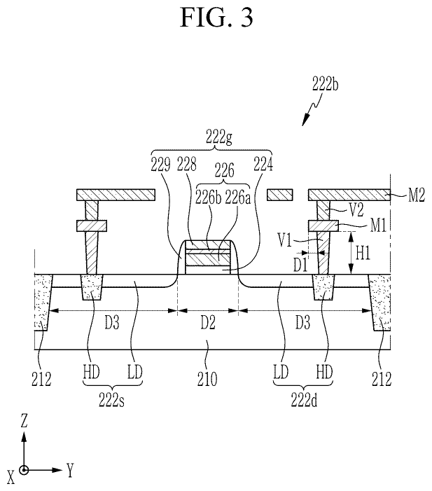

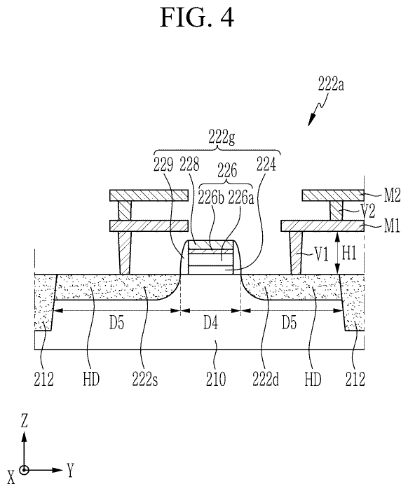

FIG. 1 is a cross-sectional view of a semiconductor device 10 according to an embodiment. FIG. 2 is an enlarged cross-sectional view of a channel structure CH in the semiconductor device 10 shown in FIG. 1. FIG. 3 and FIG. 4 are enlarged top plan views of a portion of the semiconductor device 10 shown in FIG. 1.

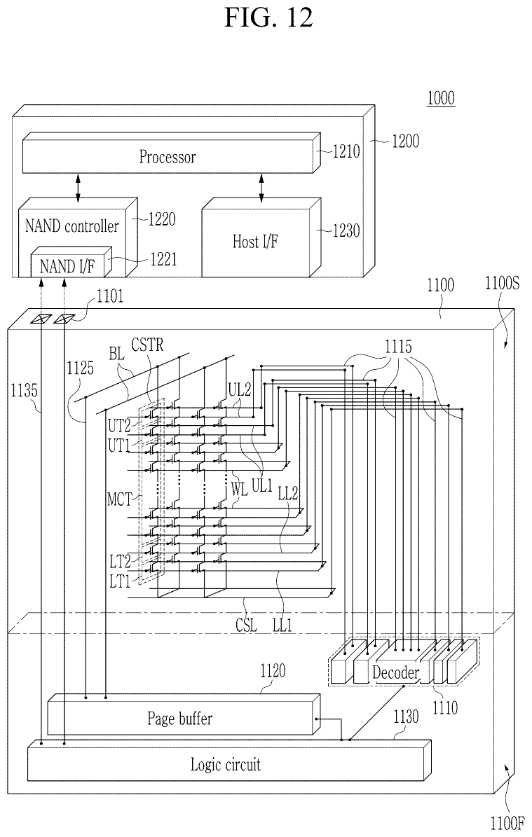

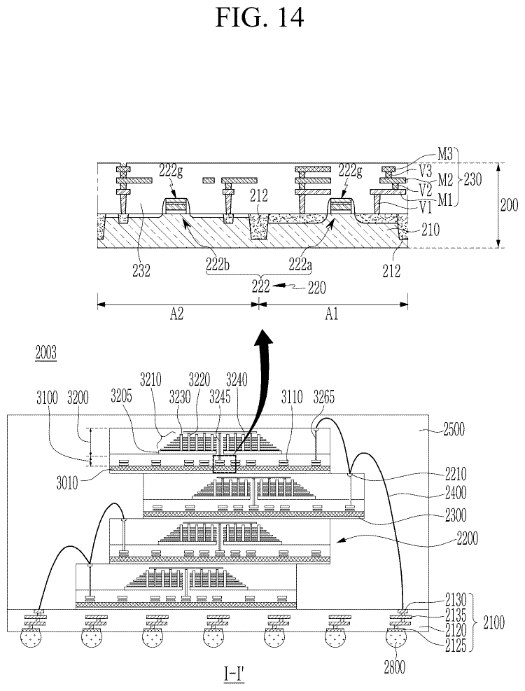

Referring to FIG. 1 and FIG. 2, a semiconductor device 10 according to an embodiment includes a cell area 100 that includes a memory cell structure and a circuit area 200 that includes a peripheral circuit structure that controls an operation of the memory cell structure. For example, in an embodiment, the circuit area 200 and the cell area 100 respectively correspond to a first structure 1100F and a second structure 1100S of a semiconductor device 1100 in an electronic system 1000 illustrated in FIG. 12. In an embodiment, the circuit area 200 and the cell area 100 respectively include a first structure 3100 and a second structure 3200 of a semiconductor chip 2200 illustrated in FIG. 14.

The circuit area 200 includes a peripheral circuit structure formed on a first substrate 210, and the cell area 100 includes a gate stacked structure 120 and a channel structure CH formed on a second substrate 110 as a memory cell structure. A first wiring portion 230 is disposed in the circuit area 200, and a second wiring portion 180 electrically connected to the memory cell structure is disposed in the cell area 100.

In an embodiment, the cell area 100 is disposed on the circuit area 200. According to this, an area that corresponds to the circuit area 200 does not need to be separately secured from the cell area 100, so an area of the semiconductor device 10 can be reduced. However, embodiments are not necessarily limited thereto, and in some embodiments, the circuit area 200 is disposed next to the cell area 100. Other variations are possible in other embodiments.

The cell area 100 includes a cell array area 102 and a connection area 104. The gate stacked structure 120 and the channel structure CH are formed on the second substrate 110 in the cell array area 102. A structure that connects the gate stacked structure 120 and/or the channel structure CH to the circuit area 200 or an external circuit may be disposed in the cell array area 102 and/or the connection area 104.

In an embodiment, the second substrate 110 includes a semiconductor layer that includes a semiconductor material. For example, the second substrate 110 is a semiconductor substrate that includes a semiconductor material or a semiconductor layer formed on a base substrate. For example, the second substrate 110 includes at least one of silicon, germanium, silicon-germanium, silicon-on-insulator (SOI), or germanium-on-insulator (GOI). P-type or n-type impurities may be doped in the semiconductor layer of the second substrate 110. For example, p-type impurities include boron, gallium, etc., and n-type impurities include phosphorus (P), arsenic (As), etc. However, embodiments are not necessarily limited to the material of the second substrate 110 or the impurities doped into the semiconductor layer, etc.

In the cell array area 102, the gate stacked structure 120 includes a cell insulating layer 132 and a gate line 130 that are alternately stacked on the first surface, such as the front surface or the upper surface, of the second substrate 110, and the channel structure CH extends in a direction, such as a Z-axis direction shown in the drawings, that crosses the second substrate 110 through the gate stacked structure 120.

In an embodiment, horizontal conductive layers 112 and 114 that electrically connect (e.g., directly connect) the channel structure CH and the second substrate 110 are disposed in the cell array region 102 between the second substrate 110 and the gate stacked structure 120. The horizontal conductive layers 112 and 114 include a first horizontal conductive layer 112 and/or a second horizontal conductive layer 114 sequentially disposed on the second substrate 110. The first horizontal conductive layer 112 is a portion of a common source line of the semiconductor device 10. For example, the first horizontal conductive layer 112 functions as the common source line along with the second substrate 110.

The first and second horizontal conductive layers 112 and 114 include a semiconductor material, such as polycrystalline silicon. For example, in an embodiment, the first horizontal conductive layer 112 includes a polycrystalline silicon layer that includes impurities. However, embodiments are not necessarily limited thereto, and in other embodiments, the second horizontal conductive layer 114 includes a material that differs from the first horizontal conductive layer 112, such as an insulating material, or the second horizontal conductive layer 114 is omitted.

The first horizontal conductive layer 112 functions as a portion of common source line of the semiconductor device 10. For example, the first horizontal conductive layer 112 functions as a common source line together with the second substrate 110. As shown in the enlarged view of FIG. 2, the channel structure CH extends to reach the second substrate 110 through the horizontal conductive layers 112 and 114, and a gate dielectric layer 150 is removed from a portion where the first horizontal conductive layer 112 is disposed, so that the first horizontal conductive layer 112 is directly connected to the channel layer 140 around the channel layer 140.

The first and second horizontal conductive layers 112 and 114 include a semiconductor material, such as polycrystalline silicon. For example, in an embodiment, the first horizontal conductive layer 112 is a polycrystalline silicon layer doped with impurities, and the second horizontal conductive layer 114 is a polycrystalline silicon layer doped with impurities or a layer that includes impurities that diffused from the first horizontal conductive layer 112. However, embodiments are not necessarily limited thereto, and in some embodiments, the second horizontal conductive layer 114 includes an insulating material. In other embodiments, the second horizontal conductive layer 114 is omitted.

The gate stacked structure 120 in which the cell insulating layer 132 and the gate line 130 are alternately stacked is disposed on the second substrate 110, such as on the first and second horizontal conductive layers 112 and 114 on the second substrate 110.

The gate line 130 includes various conductive materials. For example, the gate line 130 includes at least one of a metal such as tungsten (W), copper (Cu), or aluminum (Al), a polycrystalline silicon, a metal nitride such as titanium nitride (TiN) or tantalum nitride (TaN), etc., or a combination thereof. As shown in the enlarged view of FIG. 2, a portion, such as a first blocking layer 156a, of a blocking layer 156 made of an insulating material is disposed on an outer side of the gate line 130.

The cell insulating layer 132 includes various insulating materials. For example, the cell insulating layer 132 includes at least one of silicon oxide, silicon nitride, silicon oxynitride, a low dielectric constant material that has a smaller dielectric constant than silicon oxide, or a combination thereof.

In an embodiment, the channel structure CH passes through the gate stacked structure 120 in a direction that crosses the second substrate 110, such as a vertical direction perpendicular to the second substrate 110, which is a Z-axis direction of the drawing.

The channel structure CH includes a channel layer 140 and the gate dielectric layer 150 disposed on the channel layer 140 between the gate line 130 and the channel layer 140. In an embodiment, the channel structure CH further includes a core insulating layer 142 disposed inside the channel layer 140. However, embodiments are not necessarily limited thereto, and in some embodiments, the core insulating layer 142 is omitted. The channel structure CH further includes a channel pad 144 disposed on the channel layer 140 and/or the gate dielectric layer 150. The gate dielectric layer 150 is located between the gate line 130 and the channel layer 140 and includes a tunneling layer 152, a charge storage layer 154 and the blocking layer 156 that are sequentially formed on the channel layer 140.

Each of the channel structures CH forms one memory cell string, and a plurality of channel structures CH are disposed and spaced apart from each other, and form rows and columns in a plan view. For example, the plurality of channel structures CH are disposed in various patterns, such as a lattice pattern or a zigzag pattern, in a plan view. The channel structure CH has a pillar shape. For example, the channel structure CH has an inclined side surface so that a width thereof becomes narrower closer to the second substrate 110, depending on an aspect ratio, when viewed in a cross sectional view. However, embodiments are not necessarily limited thereto, and in other embodiments, the disposition, structure, and shape of the channel structure CH is variously modified.

The channel layer 140 includes a semiconductor material, such as polysilicon. The core insulating layer 142 includes various insulating materials. For example, the core insulating layer 142 includes at least one of silicon oxide, silicon nitride, silicon oxynitride, or a combination thereof.

The tunneling layer 152 includes an insulating material that can tunnel charges, such as silicon oxide or silicon oxynitride. The charge storage layer 154 is a data storage region, and the charge storage layer 154 includes polysilicon or silicon nitride, etc. The blocking layer 156 includes an insulating material that can prevent undesirable inflow of charge into the gate line 130. For example, the blocking layer 156 includes at least one of silicon oxide, silicon nitride, silicon oxynitride, a high dielectric constant material that has a higher dielectric constant than silicon oxide, or a combination thereof. In an embodiment, the blocking layer 156 includes a first blocking layer 156a that includes a portion that horizontally extends along the gate line 130, and a second blocking layer 156b that vertically extends between the first blocking layer 156a and the charge storage layer 154.

However, embodiments are not necessarily limited thereto, and in other embodiments, materials and stacking structures of the channel layer 140, the core insulating layer 142, and the gate dielectric layer 150 can be modified in various ways.

The channel pad 144 covers the upper surface of the core insulating layer 142 and is electrically connected to the channel layer 140. The channel pad 144 includes a conductive material, such as polycrystalline silicon doped with impurities, but is not necessarily limited thereto.

In an embodiment, the gate stacked structure 120 includes a plurality of gate stacked structures 120a and 120b that are sequentially stacked. The number of stacked gate lines 130 can be increased, thereby increasing the number of memory cells with a stable structure. FIG. 1 shows an embodiment in which the gate stacked structure 120 includes two gate stacked structures 120a and 120b, however, embodiments are not necessarily limited thereto, and in other embodiments, the gate stacked structure 120 includes one gate stacked structure or three or more gate stacked structures.

As described above, when a plurality of gate stacked structures 120a and 120b are provided, the channel structure CH includes a plurality of channel structures CH1 and CH2 that penetrate the plurality of gate stacked structures 120a and 120b, respectively, and are connected to each other. In an embodiment, each of the plurality of channel structures CH1 and CH2 has an inclined side surface so that the width becomes narrower closer to the second substrate 110 according to the aspect ratio, when viewed in a cross-sectional view, and a bent portion due to a width difference at a connection portion of the plurality of channel structures CH1 and CH2. For example, in another embodiment. the plurality of channel structures CH1 and CH2 have an inclined side surface that is continuously connected without a bent portion. FIG. 1 shows that the gate dielectric layer 150, the channel layer 140, and the core insulating layer 142 of the plurality of channel structures CH1 and CH1 extend from each other and have an integral structure. For example, in some embodiments, the gate dielectric layer 150, the channel layer 140 and the core insulation layer 142 of the plurality of channel structures CH1 and CH2 are separately formed, such that they can be electrically connected to each other, or a separate channel pad is additionally provided in the connection portion of the plurality of channel structures CH1 and CH2. The embodiments are not necessarily limited to the plurality of channel structures CH1 and CH1 shown in FIG. 1.

In an embodiment, the gate stacked structure 120 is divided into a plurality of portions in a plan view by a separation structure 146 that extends in a direction that crosses the second substrate 110, such as a perpendicular direction, which is the Z-axis direction in the drawing, and penetrates the gate stacked structure 120. In addition, an upper separation region 148 is formed in an upper portion of the gate stacked structure 120. In a plan view, a plurality of separation structures 146 and/or upper separation regions 148 extend in a first direction, which is the Y-axis direction in the drawing, and are spaced apart from each other at a predetermined interval in a second direction, which is the X-axis direction in the drawing, that crosses the first direction.

The separation structure 146 or the upper separation region 148 are filled with various insulating materials. For example, in an embodiment, the separation structure 146 and/or the upper separation region 148 include an insulating material such as at least one of silicon oxide, silicon nitride, or silicon nitride oxide. However, embodiments are not necessarily limited thereto, and in other embodiments, the structure, shape, material, etc., of the separation structure 146 and/or the upper separation region 148 can be modified in various ways.

The connection area 104 and the second wiring portion 180 connect the gate stacked structure 120 and the channel structure CH in the cell array area 102 to the circuit area 200 or an external circuit. The connection area 104 is disposed around the cell array area 102.

The second wiring portion 180 includes all components that electrically connect the gate line 130, the channel structure CH, the horizontal conductive layers 112 and 114, and/or the second substrate 110 to the circuit area 200 or an external circuit. For example, the second wiring portion 180 includes a bit line 182, a gate contact portion 184, a source contact portion, a through plug 188, a contact via 180a respectively connected to the bit line 182 and the gate contact portion 184, and a connection wiring 190 connected to the contact via 180a.

The bit line 182 extends in a second direction (X-axis direction) that crosses the first direction (Y-axis direction) in which the gate line 130 extends. The bit line 182 is electrically connected to the channel structure CH, such as the channel pad 144, through the contact via 180a that penetrates the cell insulation layer 132.

In the connection area 104, the plurality of gate contact portions 184 are electrically connected to the plurality of gate lines 130 that pass through the cell insulating layer 132 and extend into the connection area 104. The drawing shows that the plurality of gate lines 130 have a stepped shape in the connection region 104 in at least one direction, but embodiments are not necessarily limited thereto. In addition, in the connection area 104, the source contact portion pass through the cell insulating layer 132 to be electrically connected to the horizontal conductive layers 112 and 114 and/or the second substrate 110, and the through plug 188 passes through the gate stacked structure 120 or is disposed outside the gate stacked structure 120 to be electrically connected to the first wiring portion 230 of the circuit area 200.

FIG. 1 shows that the gate contact portion 184, the source contact portion, and/or the through plug 188 have inclined side surfaces so that the width thereof becomes narrower closer to the second substrate 110, according to the aspect ratio, when viewed in a cross-sectional view, and have bent portions at the boundary of the plurality of gate stacked structures 120a and 120b. However, embodiments are not necessarily limited thereto. In some embodiments, the source contact portion and/or the through plug 188 are not provided with a bent portion at the boundary portion of the plurality of gate stacked structures 120a and 120b. Various other variations are possible in other embodiments.

FIG. 1 illustrates that the connection wire 190 is provided as a single layer positioned on the same plane as the bit line 182, and a second insulating layer 192 is positioned in a portion other than the. However, this is for convenience of illustration, and embodiments are not necessarily limited thereto. Accordingly, for electrical connection to the bitline 182, the gate contact portion 184, source contact portion and/or the through plug 188, the connection wire 190 may include a plurality of wire layers, and further include a contact via.

The second wiring portion 180 is connected to the first wiring portion 230, and the bitline 182, the gate line 130, the horizontal conductive layers 112 and 114 and/or the second substrate 110 connected to the channel structure CH are electrically connected to a circuit element 220 of the circuit region 200.

The circuit area 200 include the first substrate 210, and the circuit element 220 and the first wiring portion 230 formed on the first substrate 210.

The first substrate 210 is a semiconductor substrate that includes a semiconductor material. For example, in some embodiments, the first substrate 210 is a semiconductor substrate that includes a semiconductor material, or a semiconductor substrate that includes a semiconductor layer formed on a base substrate. For example, the first substrate 210 includes at least one of monocrystalline or polycrystalline silicon, epitaxial silicon, germanium, silicon-germanium, silicon-on-insulator, or germanium-on-insulator, etc.

The circuit elements 220 formed on the first substrate 210 include various circuit elements that control operation of the memory cell structure in the cell area 100. For example, the circuit element 220 form a peripheral circuit structure such as a decoder circuit 1110 (see FIG. 12), a page buffer 1120 (see FIG. 12), a logic circuit 1130 (see FIG. 12), etc.

The circuit element 220 includes, for example, a transistor 222. In an embodiment, the circuit element 220 includes a plurality of transistors 222 that each include a first transistor 222a and a second transistor 222b, which will be described in detail below. In addition, in some embodiments, the circuit element 220 includes active elements such as a transistor 222, as well as passive elements such as a capacitor, a resistor, and an inductor.

The first wiring portion 230 disposed on the first substrate 210 is electrically connected to the circuit element 220.

The first wiring portion 230 includes a first metal layer M1, a second metal layer M2 and a third metal layer M3. FIG. 1 discloses a configuration in which the first wiring portion 230 includes the first metal layer M1, the second metal layer M2 and the third metal layer M3, but this is for convenience of illustration, and the number of metal layers is not necessarily limited thereto. In other embodiments, first wiring portion includes two metal layers, or four or more metal layers.

Referring to FIG. 1, the first metal layer M1, the second metal layer M2 and the third metal layer M3 are connected by vias V1, V2, and V3. For example, as shown in FIG. 1, a first via V1, a second via V2 and a third via V3 connect the transistor 222, the first metal layer M1, the second metal layer M2, and a third metal layer V3.

The first metal layer M1, the second metal layer M2, the third metal layer M3, the first via V1, the second via V2 and the third via V3 include various conductive materials. An insulation layer 232 is disposed between the first metal layer M1, the second metal layer M2 and the third metal layer M3 and the first via V1, the second via V2 and the third via V3, and the insulation layer 232 includes various insulating materials.

A metal layer disposed in uppermost portion adjacent to the cell region 100, such as the third metal layer M3, is provided with or configures a pad portion to which the gate contact portion 184, source contact portion, the through plug 188, etc., are connected.

Referring to FIG. 1 to FIG. 4, in an embodiment, the first substrate 210 is a semiconductor substrate that includes a first transistor region A1 and a second transistor region A2. The plurality of transistors 222 are provided on the first substrate 210. The plurality of transistors 222 include the first transistor 222a located in the first transistor region A1, and the second transistor 222b located in the second transistor region A2 and that have a greater operating voltage than the first transistor 222a.

The first transistor 222a is low voltage (LV) transistor that has a relatively low operating voltage, and the second transistor 222b is a high voltage (HV) transistor that has a relatively high operating voltage. For example, an operating voltage of the first transistor 222a is 0.1V to 10V, and an operating voltage of the second transistor 222b is 10V to 100V, higher than the first transistor 222a. However, an operating voltage of the first and second transistors 222a and 222b according to an embodiment is not necessarily limited to the above numerical range.

The low-voltage first transistor 222a has high-speed operation characteristics with excellent reliability, and can be applied to transistors that require high-speed operation. The high-voltage second transistor 222b generates a high voltage, or can be applied to a transistor that transmits a high voltage. For example, at least a portion of the transistors in the decoder circuit 1110 (see FIG. 12) and the page buffer 1120 (see FIG. 12) may be configured as the second transistor 222b.

For clear understanding and simple illustration, the drawing shows as an example that the first transistor region A1 where the first transistor 222a is located and the second transistor region A2 where the second transistor 222b is located are located together in a lower portion of the connection region 104. For example, the second transistor 222b or the second transistor region A2 are shown as being adjacent to the through plug 188, and the first transistor 222a or the first transistor region A1 are shown as being adjacent to that second transistor 222b or the second transistor region A2. For example, in an embodiment, the first transistor region A1 where the first transistor 222a is located and the second transistor region A2 where the second transistor 222b is located are located together in a lower portion of the cell array region 102. In an embodiment, at least one of the first transistor region A1 where the first transistor 222a is located and the second transistor region A2 where the second transistor 222b is located is located in the lower portion of the cell array region 102, and the other is located in the connection region 104. In other embodiments, locations of the first transistor region A1 and the second transistor region A2 can be modified in various ways.

In an embodiment, the plurality of transistors 222, such as the first transistor 222a and the second transistor 222b, have a planar structure. For example, referring to both FIG. 3 and FIG. 4, each of the plurality of transistors 222 includes a gate structure 222g disposed on the first substrate 210, and source and drain regions 222s and 222d formed by doping a portion of the first substrate 210. The gate structure 222g includes a gate insulation layer 224, a gate electrode 226, a gate capping layer 228, and a gate spacer 229.

The gate insulation layer 224 includes at least one of a high dielectric constant material that has a higher dielectric constant than an oxide, a nitride, an oxidation nitride, or silicon oxide, or a low dielectric constant material that has a lower dielectric constant than silicon oxide. For example, the gate insulation layer 224 includes at least one of silicon oxide, silicon nitride, silicon nitride oxide, hafnium oxide, aluminum oxide or tantalum oxide. The gate insulation layer 224 may be formed as a single insulation layer, or may include a plurality of insulation layers.

The gate electrode 226 disposed on the gate insulation layer 224 includes a conductive material. For example, the gate electrode 226 includes at least one of a metal, a metal alloy, a metal nitride, a metal silicide, or a doped semiconductor material. The metal or metal alloy in the gate electrode 226 include at least one of titanium, tungsten, molybdenum, aluminum, copper, cobalt, tantalum or ruthenium. The metal nitride in the gate electrode 226 includes at least one of titanium nitride, tungsten nitride, molybdenum nitride or tantalum nitride. The gate electrode 226 may further include a metal oxide or a metal nitride oxide obtained when the above material is oxidized. The semiconductor material doped with impurities is a semiconductor material, such as a polycrystalline semiconductor material, doped with n-type or p-type impurities.

The drawing shows that the gate electrode 226 includes a first electrode layer 226a formed as a semiconductor layer, and a second electrode layer 226b formed as a metal-containing layer that includes a metal. However, embodiments are not necessarily limited thereto, and in other embodiments, the material, stacking structure, etc., of the gate electrode 226 can be modified in various ways.

The gate capping layer 228 is disposed on the gate electrode 226. The gate capping layer 228 includes various insulating materials, such as an oxide, a nitride, or a nitride oxide. For example, the gate capping layer 228 includes at least one of silicon oxide, silicon nitride or silicon nitride oxide. The gate capping layer 228 functions as a mask layer when forming the gate insulation layer 224 and the gate electrode 226. The drawing shows that the gate spacer 229 is located on a side surface of the gate capping layer 228, however, in other embodiments, the gate capping layer 228 is disposed on the gate spacer 229.

The gate spacer 229 includes various insulating materials, such as at least one of an oxide, a nitride, a nitride oxide or a low dielectric constant material. For example, the gate spacer 229 includes at least one of silicon oxide, silicon nitride or silicon nitride oxide, or is formed of a material that further includes carbon. The gate spacer 229 may be formed as a single insulation layer, and may include a plurality of insulation layers.

The gate spacer 229 is located on a side surface of the gate structure 222g, and insulates the gate structure 222g, and the source and drain regions 222s and 222d. For example, the gate spacer 229 is located on both side surfaces in a cross section along the Y-axis direction in the drawing that crosses at least the gate electrode 226, and extends along an elongation direction, such as the X-axis direction in the drawing, of the gate electrode 226.

However, embodiments are not necessarily limited to the above, and in other embodiments, the gate insulation layer 224, the gate electrode 226, the gate capping layer 228, the gate spacer 229 and/or the source and drain regions 222s and 222d have various other materials and structures, etc.

In a plan view, the source and drain regions 222s and 222d are located in a portion of the first substrate 210 located on both sides of the gate structure 222g. For example, the source and drain regions 222s and 222d are portions of the first substrate 210 doped with n-type impurities or p-type impurities. The conductivity type of impurities of the source and drain regions 222s and 222d is opposite to the conductivity type of the impurities in the first substrate 210.

Referring to FIG. 3, in an embodiment, a source region 222s and a drain region 222d of the second transistor 222b include a low-concentration doped region LD and a high-concentration doped region HD.

The low-concentration doped region LD includes most of the source region 222s and the drain region 222d of the second transistor 222b. For example, the impurity doping concentration in the low-concentration doped region LD is 10¹⁵ cm⁻³ to 10¹⁷ cm⁻³. In addition, referring to FIG. 3, the high-concentration doped region HD is located in a portion where the source region 222s and the drain region 222d of the second transistor 222b and the first via V1 contact each other. The impurity doping concentration of the high-concentration doped region HD is higher than the impurity doping concentration of the low-concentration doped region LD.

The low-concentration doped region LD is located between the high-concentration doped region HD and the gate electrode 226. Accordingly, a high voltage transmitted through a plurality of metal layers M1, M2, and M3 and the vias V1, V2, and V3 decreases while passing through the low-concentration doped region LD. Accordingly, damage of the gate electrode 226 due to the high voltage can be prevented. For example, even if a high voltage of 30 V is transmitted through the plurality of metal layers M1, M2, and M3 and the vias V1, V2, and V3, the voltage decreases while passing through the low-concentration doped region LD, and the gate electrode 226 receives a voltage of only 10 V. However, these numeral values are examples, and embodiments of present disclosure are not necessarily limited thereto.

Referring to FIG. 4, in the first transistor 222a, the source region 222s and the drain region 222d include the high-concentration doped region HD. This is because, since the first transistor 222a receives a lower voltage than the second transistor 222b, damage of the gate electrode 226 due to the high voltage is not problematic, and accordingly, a separate voltage drop in the source region 222s and the drain region 222d is not needed.

In an embodiment, a device isolation portion 212 is disposed in a first surface, such as a front surface or an upper surface, of the first substrate 210. The device isolation portion 212 is located on a boundary of the first transistor region A1 and the second transistor region A2. The device isolation portion 212 separates each active region that corresponds to the first and second transistors 222a and 222b in the first transistor region A1 and the second transistor region A2 on the front surface of the first substrate 210. For example, the device isolation portion 212 separates the source and drain regions 222s and 222d of the plurality of transistors 222 on the front surface of the first substrate 210.

For example, the device isolation portion 212 is an insulating portion that has a shallow trench isolation (STI) structure that separates an active region of the first and second transistors 222a and 222b. The device isolation portion 212 may be filled with various insulating materials. For example, the device isolation portion 212 includes an insulating material such as one of an oxide, a nitride, or a nitride oxide. For example, the device isolation portion 212 includes an insulating material such as at least one of silicon oxide, silicon nitride, or silicon nitride oxide. However, embodiments are not necessarily limited thereto, and in other embodiments, the material, etc., of the device isolation portion 212 can be modified in various ways.

Referring to FIG. 3 and FIG. 4, in a semiconductor device according to an embodiment, arrangement forms of the first metal layer M1 of the first transistor 222a and the second transistor 222b are different.

Referring to FIG. 3, in an embodiment, the first metal layer M1 that overlaps the high-voltage second transistor 222b does not overlap another neighboring high voltage transistor. For example, the first metal layer M1 that overlaps the high-voltage second transistor 222b does not include a wire that overlaps another second transistor 222b. The first metal layer M1 that overlaps in a direction (Z direction) perpendicular to the surface of the first substrate 210 and the second transistor 222b overlaps one second transistor 222b, and transmits the voltage in the direction (Z direction) perpendicular to the surface of the first substrate 210.

For example, in the second transistor 222b, the first metal layer M1 does not function as a wire that transmits the voltage in a horizontal direction (Y direction or X direction) parallel to the surface of the first substrate 210, and functions as a pad that connects the first via V1 located below the first metal layer M1 and the second via V2 located above it. Accordingly, the first metal layer M1 of the second transistor does not directly contact a wire of another neighboring second transistor.

Referring to FIG. 3, in an embodiment, a distance D1 between one edge of the first via V1 and one edge of the first metal layer M1 is less than 300 nm. For example, as shown in FIG. 3, the distance D1 between one edge of the first via V1 and one edge of the first metal layer M1 is in a direction that approaches the gate structure 222g. When the distance D1 between the first via V1 and the first metal layer M1 is 300 nm or more, the first metal layer M1 is located close to the gate structure 222g, the region where the first metal layer M1 and the source region 222s and/or the drain region 222d overlap is enlarged. However, a high voltage of the first metal layer M1 can affect performance of the second transistor 222b.

For a stable contact between the first via V1 and the first metal layer M1, an area of the first metal layer M1 in a plan view is greater than an area of the first via V1 in a plan view. For example, a distance between one edge of the first via V1 and one edge of the first metal layer M1 is 0.1 nm or more. However, this is an example, and embodiments of the present disclosure are not necessarily limited thereto.

Referring to FIG. 4, in an embodiment, the low-voltage first transistor 222a includes a wire through which the first metal layer M1 transmits the voltage in the horizontal direction (X direction or Y direction) parallel to the surface of the first substrate 210. Accordingly, the first metal layer M1 of the first transistor 222a overlaps a plurality of transistors, and overlaps another neighboring transistor while transmitting the applied voltage in the horizontal direction (X direction or Y direction) parallel to the surface of the first substrate 210. For example, the first metal layer M1 of the first transistor directly contacts a wire of another neighboring first transistor.

For example, a difference lies in that, in a semiconductor device according to an embodiment, the first metal layer M1 of the first transistor 222a functions as a wire, and the first metal layer M1 of the second transistor 222b functions as a pad.

In the high-voltage second transistor 222b that transmits a high voltage, when a distance H1 between the first metal layer M1 and the source and drain regions 222s and 222d is short, the source region 222s and the drain region 222d can be affected by the high voltage. For example, as described above, the source region 222s and the drain region 222d of the high-voltage second transistor 222b include a low-concentration doped region LD, and when the first metal layer M1 that transmits a high voltage is disposed on the low-concentration doped region LD, the characteristics of the low-concentration doped region LD can be affected. For example, a voltage drop effect in the low-concentration doped region LD might not be sufficient for the high voltage of the first metal layer M1, and can cause high voltage damage to the gate electrode 226 of the second transistor 222b.

In addition, because the high electric field is applied between the first metal layer M1 and the second transistor 222b, due to such electric field, abnormal behaviors of the second transistor 222b, such as Ion degradation, Ioff increase, and/or breakdown voltage (BV) degradation of the second transistor 222b, can be generated.

However, to prevent performance degradation of the high-voltage second transistor 222b, when the distance H1 of between the first metal layer M1 and the source region 222s and the drain region 222d is increased, integration of the low-voltage first transistor 222a becomes challenging.

The low-voltage first transistor 222a is smaller than the high-voltage second transistor 222b. Accordingly, when the distance H1 between the first metal layer M1 and the source region 222s and the drain region 222d in the low-voltage first transistor 222a increases, a process of forming the first via V1 becomes challenging. For example, the first via V1 in formed in the narrow source region 222s and the drain region 222d of the low-voltage first transistor 222a, has a narrow and deep shape. When the distance H1 between the first metal layer M1 and the source region 222s and the drain region 222d increases, during a process of forming the first via V1, a hole might not vertically form, and bending or twisting may occur.

Referring to FIG. 3, in an embodiment, a width D2 along a Y direction of the gate structure of the second transistor 222b is 400 nm to 2 μm. In addition, a width D3 along the Y direction of the source region and the drain region of the second transistor 222b is 1000 nm to 2000 nm. However, this size is an example, and the size of the second transistor can vary depending on the applied voltage.

In addition, referring to FIG. 4, in an embodiment, a width D4 along the Y direction of the gate structure 222g of the first transistor 222a is 20 nm to 40 nm. In addition, a width D5 along Y direction of the source region and the drain region of the first transistor is 50 nm to 150 nm. However, this size is an example, and the size of the first transistor can vary depending on the applied voltage.

Because the first transistor 222a is smaller than the second transistor 222b, a distance in a plan view between the first metal layer M1 and the gate electrode 226 of the first transistor 222a is less than a distance in a plan view between the first metal layer M1 and the gate electrode 226 of the second transistor 222b.

For example, because the low-voltage first transistor 222a is smaller than the high-voltage second transistor 222b, the area of the source region 222s and the drain region 222d with which the first via V1 is in contact is also small, and accordingly, it is challenging to form a hole for forming the first via V1 in that narrow area. Accordingly, when the distance H1 between the first metal layer M1 and the source region 222s and the drain region 222d increases, to secure process margin, the size of the source region 222s and the drain region 222d also increases. Accordingly, when the distance H1 between the first metal layer Ml and the source region 222s and the drain region 222d increases, reducing the size of the first transistor 222a and improving integration becomes more challenging.

For example, the optimal distance H1 between the first metal layer M1 and the source region 222s and the drain region 222d for the low-voltage first transistor 222a and the high-voltage second transistor 222b are different. Accordingly, a semiconductor device according to an embodiment includes a pad to which the first via V1 and the second via V2 are disposed above and below, respectively, by minimizing the area in a plan view of the first metal layer M1 of the high-voltage second transistor 222b. Accordingly, an overlapping region of the first metal layer M1 and the second transistor 222b is minimized, integration of the low-voltage first transistor 222a is maintained, and abnormal behavior of the high-voltage second transistor 222b due to a high voltage can be prevented.

The second metal layer M2 in the high-voltage second transistor 222b overlaps a neighboring second transistor 222b and includes a wire, and a voltage can be transmitted to the second substrate 110 in the horizontal direction through the second metal layer M2.

For example, in a semiconductor device according to an embodiment, the first metal layer M1 of the high-voltage second transistor 222b does not overlap another neighboring transistor, and the first metal layer M1 of the low-voltage first transistor 222a overlaps another neighboring transistor. Hereinafter, an arrangement in a plan view of the second transistor 222b and the first transistor 222a will be described as an example.

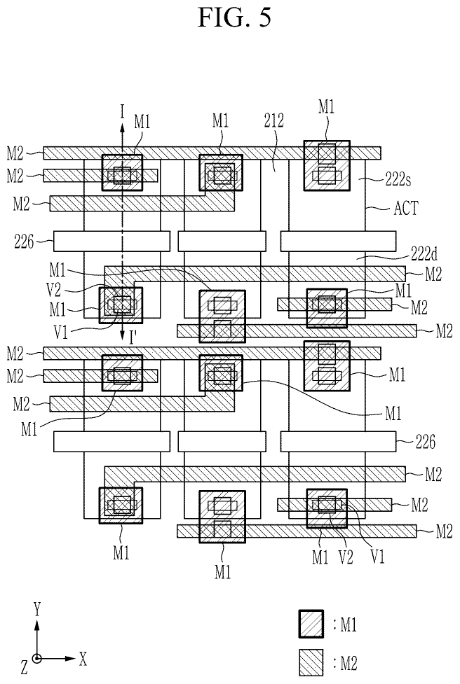

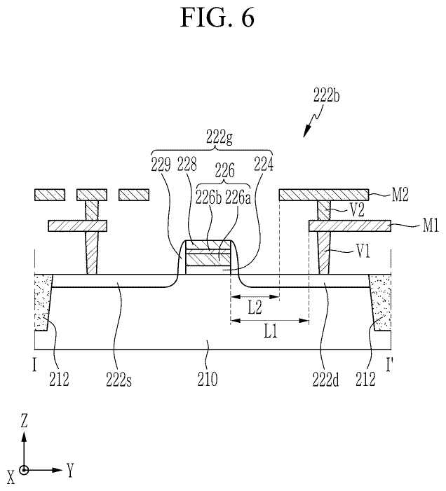

FIG. 5 shows an arrangement in a plan view of the second transistor 222b according to an embodiment. FIG. 6 is a cross-sectional view taken along line I-I′ of FIG. 5. In FIG. 5 and FIG. 6, the first via V1, the second via V2, the first metal layer M1, and the second metal layer M2 are shown. However, the arrangement in a plan view of FIG. 5 is an example, and embodiments of the present disclosure are not necessarily limited thereto.

Referring to FIG. 5, in an embodiment, a plurality of active regions ACT are defined by the device isolation portion 212. The source region 222s and the drain region 222d are located within each active region ACT. As shown in FIG. 5, the gate electrode 226 is located along the second direction (X direction) within each active region ACT.

Referring to FIG. 5, the first metal layer M1 overlaps one active region ACT but does not overlap another neighboring active region ACT. For example, whereas the second metal layer M2 extends along the second direction (X direction) and overlaps the plurality of active regions ACT, the first metal layer M1 located closer to the active region ACT than the second metal layer M2, overlaps one active region ACT to function as a pad that connects the first via V1 and the second via V2 in the vertical direction, but does not overlap another neighboring active region ACT. Accordingly, an overlapping region of the first metal layer M1 and the active region ACT is minimized.

For example, the first metal layer M1 that is located close to the active region ACT has a pad form that does not cross the active region ACT, and accordingly, a high voltage of the first metal layer M1 does not affect the performance of the transistor.

As shown in FIG. 6, in an embodiment, a distance L2 between the gate electrode 226 and the second metal layer M2 located closest to the gate electrode 226 is shorter than a distance L1 between the gate electrode 226 and the first metal layer M1 located closest to the gate electrode 226. For example, in the cross-section of FIG. 6, the second metal layer M2 is located closer to the gate electrode 226 than the first metal layer M1. This structure results from, in the second transistor 222b, in a plan view, the second metal layer M2 being located across the active region ACT.

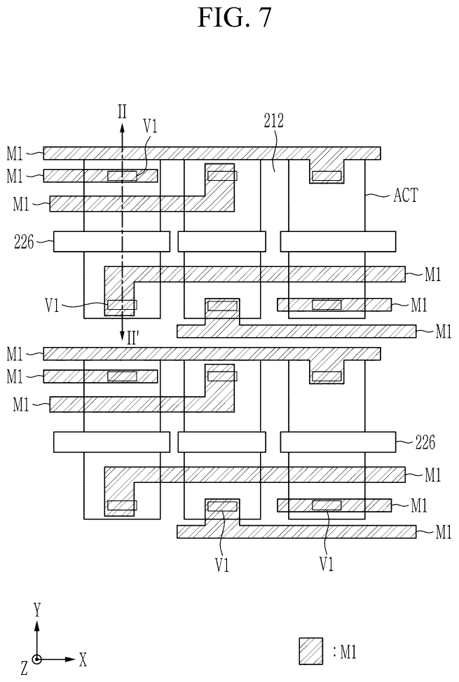

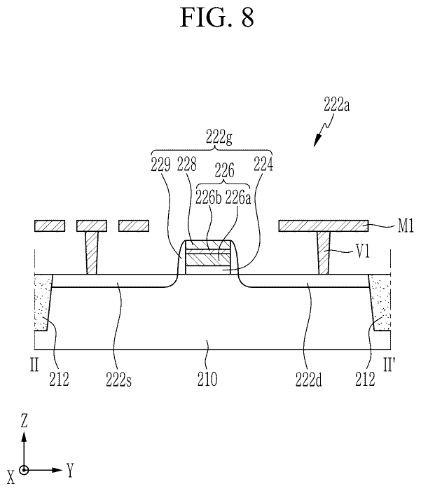

FIG. 7 shows an arrangement in a plan view of the first transistor 222a according to an embodiment. FIG. 8 is a cross-sectional view taken along line II-II' of FIG. 7. In FIG. 7 and FIG. 8, the first via V1 and the first metal layer M1 are shown. The arrangement form of the second metal layer M2 is not shown in the first transistor 222a in FIG. 7, for easier comparison of the first metal layer M1 of the first transistor 222a and the first metal layer M1 of the second transistor 222b, and in FIG. 8, the first via V1 and the first metal layer M1 are shown, but the second via and the second metal layer are not shown.

Referring to FIG. 7 and FIG. 8, in an embodiment, in the first transistor 222a, the first metal layer M1 has a wire form that overlaps the plurality of active regions ACT. As shown in FIG. 7, the first metal layer M1 extends along the second direction (X direction). For example, when FIG. 5 and FIG. 7 are compared, a difference lies in that, in the second transistor 222b of FIG. 5, the first metal layer M1 has a pad form that overlaps one active region ACT, but in the first transistor 222a of FIG. 7, the first metal layer M1 has a wire form that overlaps the plurality of active regions ACT. This is because, as described above, the first transistor 222a receives the low voltage, and thus, even if the distance between the first metal layer M1 and the first transistor 222a is close, the first metal layer M1 can affect an operation of the first transistor 222a. In addition, if the distance between the first metal layer M1 and the first transistor 222a is close, the process of forming the first via V1 becomes easier. The first transistor 222a that transmits a low voltage is smaller than the second transistor 222b that transmits a high voltage, and thus, when forming the first via V1, the distance H1 between the first metal layer M1 and the first transistor 222a should be close. As shown in FIG. 7, the first metal layer M1 of the first transistor 222a extends across the active region ACT.

In the above, an embodiment in which the first metal layer overlaps the second transistor 222b M1 and transmits a high voltage has a pad shape, and the second metal layer M2 has a wire shape, but in another embodiment, the first metal layer M1 and the second metal layer M2 each have a pad shape and the third metal layer M3 has a wire shape.

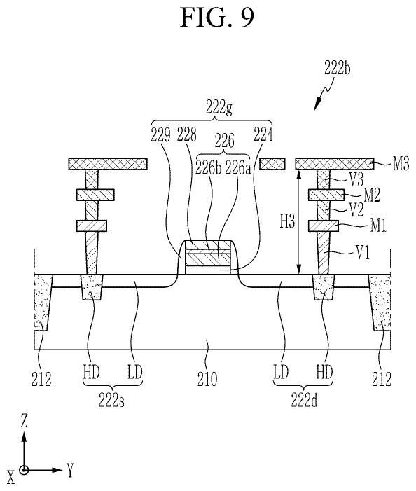

FIG. 9 shows the same cross-section as FIG. 5, with respect to a semiconductor device according to another embodiment. Referring to FIG. 9, a semiconductor device according to an embodiment is identical to an embodiment of FIG. 5, except that the first metal layer M1 and the second metal layer M2 have a pad form, and the third metal layer M3 has a wire form. A repeated description of the same components will be omitted. Referring to FIG. 9, in an embodiment, the second metal layer M2 of FIG. 9 has a pad form that is the same as that of the first metal layer M1. Therefore, the second metal layer M2 is a pad that overlaps one active region ACT and connects the second via V2 and the third via V3 in the vertical direction, and does not overlap another neighboring active region ACT, in a plan view. Accordingly, a distance H3 between the source region 222s and the drain region 222d of the second transistor 222b and the third metal layer M3 that functions as a wire is greater than in a previous embodiment. Accordingly, even if a high voltage is applied to the third metal layer M3, because the distance between the third metal layer M3 and the second transistor 222b is wide, performance degradation of the second transistor 222b due to the high voltage can be prevented.

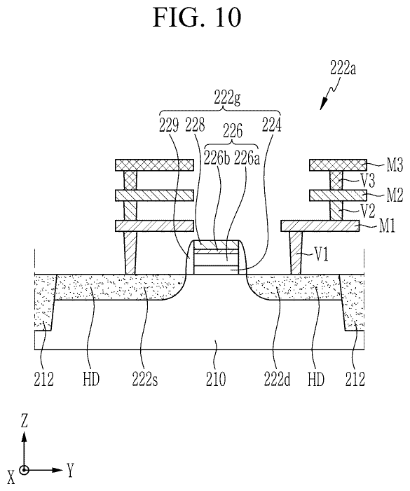

FIG. 10 shows the same cross-section as FIG. 8, with respect to a semiconductor device according to another embodiment. Referring to FIG. 10, a semiconductor device according to an embodiment includes the first transistor 222a to which a low voltage is applied, and the first metal layer M1, the second metal layer M2 and the third metal layer M3 all have wire forms. As described above, because a low voltage is applied to the first transistor 222a, even if the distance between the first transistor 222a and the wire through which the voltage is transmitted is small, performance of the first transistor 222a is be affected, forming the first via V1 is easy, and the size of the first transistor 222a can be reduced.

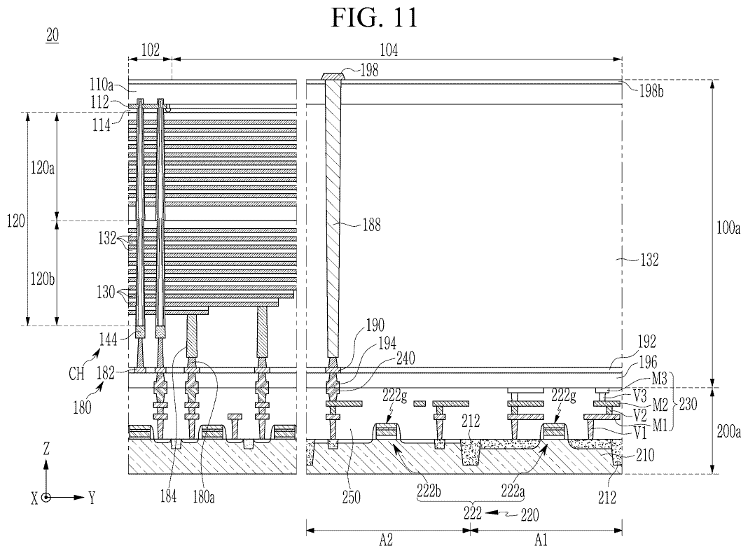

An additional embodiment and its variation that differs from an above-described embodiment will be described in detail with reference to FIG. 11. Repeated descriptions of components that are the same or similar to those described above may be omitted or summarized, except where otherwise noted. Hereinafter, the description will focus on parts that differ from those described above.

FIG. 11 is a cross-sectional view of a semiconductor device 20 according to an embodiment.

Referring to FIG. 11, the semiconductor device 20 according to the embodiment has a chip-to-chip (C2C) structure bonded by a wafer bonding method. For example, after manufacturing a lower chip that includes a circuit area 200a formed on a first substrate 210 and an upper chip that includes a cell area 100a formed on a second substrate 110a, the semiconductor device 20 is manufactured by bonding them.

The circuit area 200a includes the first substrate 210, a circuit element 220, a first wiring portion 230, and a first bonding structure 240 electrically connected to the first wiring portion 230 and disposed on a surface that faces the cell area 100a. A first insulating layer 250 covers an area other than the first bonding structure 240 on a surface that faces the cell area 100a.

The cell area 100a includes the second substrate 110a, a gate stacked structure 120, a channel structure CH, a second wiring portion 180, and a second bonding structure 194 electrically connected to the second wiring portion 180 and disposed on a surface that faces the circuit area 200a. An insulating layer 196 covers an area other than the second bonding structure 194.

In an embodiment, the second substrate 110a is a semiconductor substrate that includes a semiconductor material. For example, the second substrate 110a may be made of a semiconductor material, or it may include a semiconductor layer formed on a base substrate. For example, in an embodiment, the second substrate 110a may include at least one of monocrystalline or polycrystalline silicon, germanium, silicon-germanium, silicon-on-insulator, or germanium-on-insulator. In an embodiment, the second substrate 110a includes an insulating layer or a support member that includes an insulating material. After the cell area 100a is bonded to the circuit area 200a, the semiconductor substrate in the cell area 100a is removed, and a support member that includes an insulating layer or an insulating material is formed.

In an embodiment, the gate stacked structure 120 is sequentially stacked on the lower portion of the second substrate 110a, and has a structure in which the gate stacked structure 120 shown in FIG. 1 is vertically inverted. In addition, the channel structure CH that passes through the gate stacked structure 120 also has a structure in that the channel structure CH shown in FIG. 2 is vertically inverted. Accordingly, when the channel structure CH is viewed in a cross sectional view, it has an inclined side surface whose width narrows from the circuit area 200a toward the second substrate 110a. In addition, a channel pad 144 and the second wiring portion 180a disposed on the gate stacked structure 120 are adjacent to the circuit area 200a.

For example, the first bonding structure 240 and/or the second bonding structure 194 include at least one of aluminum, copper, tungsten, or an alloy thereof. For example, the first and second bonding structures 240 and 194 include copper, so that the cell area 100a and the circuit area 200a are bonded (for example, bonded by direct contact) by copper-to-copper bonding.

Although FIG. 11 shows that the gate stacked structure 120 includes a plurality of gate stacked structures, embodiments are not necessarily limited thereto, and in other embodiments, the gate stacked structure 120 includes one or three or more gate stacked structures. Except for those described separately, the gate stacked structure 120 and the channel structure CH are the same as those described with reference to FIG. 1 and FIG. 2. FIG. 11 shows that an electrical connection structure between the channel structure CH and the horizontal conductive layers 112 and 114 and/or the second substrate 110a is same as that in FIG. 2. However, embodiments are not necessarily limited thereto, and in other embodiments, an electrical connection structure between the channel structure CH and the horizontal conductive layers 112 and 114 and/or the second substrate 110a can variously change.

The semiconductor device 20 according to an embodiment includes an input/output pad 198 and the through plug 188 or an input/output connection wire electrically connected thereto. The through plug 188 or the input/output connection wire is electrically connected to a portion of the second bonding structure 194. The input/output pad 198 is disposed, for example, on the insulating film 198b that covers the outer surface of the second substrate 110a. Some embodiments provide a separate input/output pad electrically connected to the circuit area 200a.

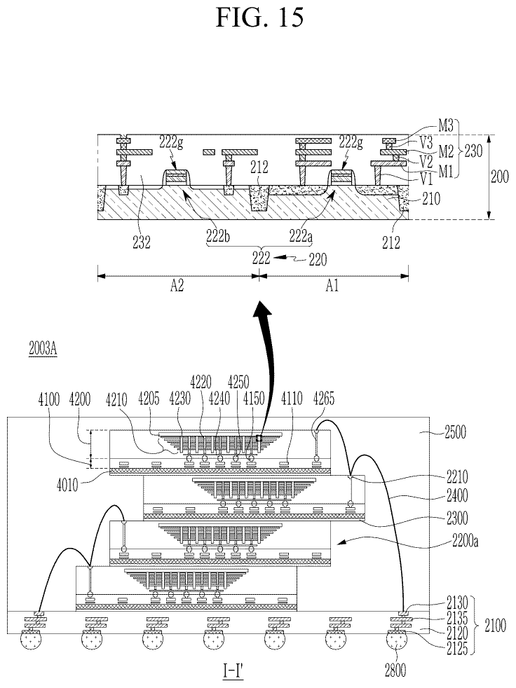

In an embodiment, the circuit area 200a and the cell area 100a respectively correspond to a first structure 1100F and a second structure 1100S of a semiconductor device 1100 included in an electronic system 1000 illustrated in FIG. 12. In an embodiment, the circuit area 200a and the cell area 100a respectively include a first structure 4100 and a second structure 4200 of a semiconductor chip 2200a illustrated in FIG. 15.

An example of an electronic system that includes a semiconductor device described above will be hereinafter described in detail.

FIG. 12 shows an electronic system that includes a semiconductor device according to an embodiment.

Referring to FIG. 12, an electronic system 1000 according to an embodiment includes a semiconductor device 1100 and a controller 1200 electrically connected to the semiconductor device 1100. The electronic system 1000 may be a storage device that includes one or more semiconductor devices 1100, or an electronic device that includes the storage device. For example, the electronic system 1000 is one of a solid state drive device (SSD device), a universal serial bus (USB), a computing system, a medical device, or a communication device that includes one or more semiconductor devices 1100.

The semiconductor device 1100 is a non-volatile memory device, and is, for example, a NAND flash memory device described with reference to FIG. 1 to FIG. 11. The semiconductor device 1100 includes a first structure 1100F and a second structure 1100S on the first structure 1100F. In an embodiment, the first structure 1100F is disposed next to the second structure 1100S. The first structure 1100F is a peripheral circuit structure that includes a decoder circuit 1110, a page buffer 1120, and a logic circuit 1130. The second structure 1100S is a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, respective memory cell strings CSTR include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 varies according to embodiments.

In an embodiment, the lower transistors LT1 and LT2 include a ground selection transistor, and the upper transistors UT1 and UT2 include a string selection transistor. The first and second gate lower lines LL1 and LL2 are gate lines of the lower transistors LT1 and LT2, respectively. The word line WL is a gate line of the memory cell transistor MCT, and the gate upper lines UL1 and UL2 are gate lines of the upper transistors UT1 and UT2, respectively.

The common source line CSL, the first and second gate lower lines LL1 and LL2, the word line WL, and the first and second gate upper lines UL1 and UL2 are electrically connected to the decoder circuit 1110 through a first connection wiring 1115 that extends from the first structure 1100F to the second structure 1100S. The bit line BL is electrically connected to the page buffer 1120 through a second connection wiring 1125 that extends from the first structure 1100F to the second structure 1100S.

In the first structure 1100F, the decoder circuit 1110 and the page buffer 1120 perform a control operation on at least one memory cell transistor of the plurality of memory cell transistors MCT. The decoder circuit 1110 and the page buffer 1120 are controlled by the logic circuit 1130. The semiconductor device 1100 communicates with the controller 1200 through an input/output pad 1101 electrically connected to the logic circuit 1130. The input/output pad 1101 is electrically connected to the logic circuit 1130 through an input/output connection wiring 1135 that extends from the first structure 1100F to the second structure 1100S.

The controller 1200 includes a processor 1210, a NAND controller 1220, and a host interface 1230. In some embodiments, the electronic system 1000 includes a plurality of semiconductor devices 1100, and the controller 1200 controls the plurality of semiconductor devices 1100.

The processor 1210 controls an overall operation of the electronic system 1000. The processor 1210 operates according to predetermined firmware, and accesses the semiconductor device 1100 by controlling the NAND controller 1220. The NAND controller 1220 includes a NAND interface 1221 that processes communication with the semiconductor device 1100. Through the NAND interface 1221, a control command that controls the semiconductor device 1100, data to be written to the memory cell transistor MCT of the semiconductor device 1100, data to be read from the memory cell transistor MCT of the semiconductor device 1100 etc., can be transmitted. The host interface 1230 provides a communication function between the electronic system 1000 and an external host. When a control command is received from an external host through the host interface 1230, the processor 1210 controls the semiconductor device 1100 in response to the control command.

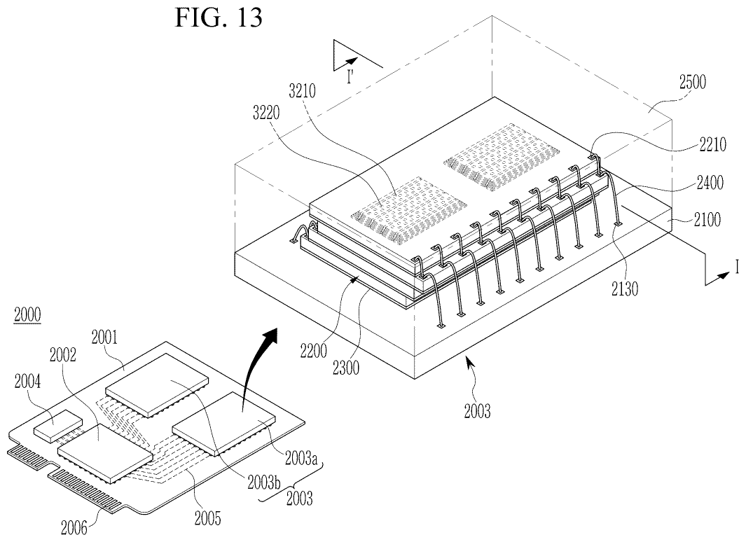

FIG. 13 is a perspective view of an electronic system that includes a semiconductor device according to an embodiment.

Referring to FIG. 13, an electronic system 2000 according to an embodiment includes a main substrate 2001, a controller 2002 mounted on the main substrate 2001, one or more semiconductor packages 2003, and a DRAM 2004. The semiconductor package 2003 and the DRAM 2004 are connected to the controller 2002 by a wiring pattern 2005 formed on the main substrate 2001.

The main substrate 2001 includes a connector 2006 that includes a plurality of pins coupled to an external host. The number and disposition of the plurality of pins in the connector 2006 varies depending on the communication interface between the electronic system 2000 and the external host. In an embodiment, the electronic system 2000 communicates with an external host using an interface, such as one of a universal serial bus (USB), a peripheral component interconnect express (PCI-Express), a serial advanced technology attachment (SATA), or a M-Phy for universal flash storage (UFS). In an embodiment, the electronic system 2000 operates with power supplied from an external host through the connector 2006. The electronic system 2000 further includes a power management integrated circuit (PMIC) that distributes power received from the external host to the controller 2002 and the semiconductor package 2003.

The controller 2002 writes data to the semiconductor package 2003 or reads data from the semiconductor package 2003, and increases the operating speed of the electronic system 2000.

The DRAM 2004 is a buffer memory that alleviates a speed difference between the semiconductor package 2003 and an external host. The DRAM 2004 in the electronic system 2000 operates as a kind of cache memory, and provides space for temporarily storing data in control operations or the semiconductor package 2003. When the electronic system 2000 includes the DRAM 2004, the controller 2002 further includes a DRAM controller that controls the DRAM 2004 in addition to the NAND controller that controls the semiconductor package 2003.

The semiconductor package 2003 includes first and second semiconductor packages 2003a and 2003b spaced apart from each other. Each of the first and second semiconductor packages 2003a and 2003b is a semiconductor package that includes a plurality of semiconductor chips 2200. Each of the first and second semiconductor packages 2003a and 2003b include a package substrate 2100, a semiconductor chip 2200 on the package substrate 2100, an adhesive layer 2300 disposed on a lower surface of each of the semiconductor chips 2200, a connection structure 2400 that electrically connects the semiconductor chip 2200 to the package substrate 2100, and a molding layer 2500 that covers the semiconductor chip 2200 and the connection structure 2400 on the package substrate 2100.

The package substrate 2100 is a printed circuit board that includes a package upper pad 2130. Each semiconductor chip 2200 includes an input/output pad 2210. The input/output pad 2210 corresponds to the input/output pad 1101 in FIG. 12. Each semiconductor chip 2200 includes a gate stacked structure 3210 and a channel structure 3220. Each semiconductor chip 2200 includes a semiconductor device described with reference to FIG. 1 to FIG. 11.

In an embodiment, the connection structure 2400 is a bonding wire that electrically connects the input/output pad 2210 to the package upper pad 2130. Accordingly, in each of the first and second semiconductor packages 2003a and 2003b, the semiconductor chips 2200 are electrically connected to each other using a bonding wiring method, and are electrically connected to the package upper pad 2130 of the package substrate 2100. In some embodiments, in each of the first and second semiconductor packages 2003a and 2003b, the semiconductor chips 2200 are electrically connected to each other by a connection structure that includes a through silicon via (TSV) instead of the connection structure 2400 that uses the bonding wiring method.

In an embodiment, the controller 2002 and the semiconductor chip 2200 are included in one package. For example, the controller 2002 and the semiconductor chip 2200 are mounted on a separate interposer substrate that differs from the main substrate 2001, and the controller 2002 and the semiconductor chip 2200 are connected to each other by wiring formed on the interposer substrate.

FIG. 14 and FIG. 15 are cross-sectional views of a semiconductor package according to an embodiment. FIG. 14 and FIG. 15 each illustrate an embodiment of the semiconductor package 2003 of FIG. 12, and conceptually show a region of the semiconductor package 2003 of FIG. 12 in a cross-section taken along line I-I′.

Referring to FIG. 14, in an embodiment, the package substrate 2100 of the semiconductor package 2003 is a printed circuit board. The package substrate 2100 includes a package substrate body portion 2120, a package upper pad 2130 disposed on an upper surface of the package substrate body portion 2120, a package lower pad 2125 disposed on a lower surface of the package substrate body portion 2120 or exposed through the lower surface, and an internal wiring 2135 that electrically connects the package upper pad 2130 and the package lower pad 2125 inside the package substrate body portion 2120. The package upper pad 2130 is electrically connected to the connection structure 2400. The package lower pad 2125 is connected to the wiring pattern 2005 of the main substrate 2001 of the electronic system 2000 as shown in FIG. 13 through a conductive connection portion 2800.

The semiconductor chip 2200 includes a semiconductor substrate 3010 and a first structure 3100 and a second structure 3200 sequentially stacked on the semiconductor substrate 3010. The first structure 3100 includes a peripheral circuit area that includes a peripheral wiring 3110. The second structure 3200 includes a common source line 3205, a gate stacked structure 3210 on the common source line 3205, a channel structure 3220 and a separation structure 3230 that penetrate the gate stacked structure 3210, a bit line 3240 electrically connected to the channel structure 3220, and a gate connection wiring electrically connected to the word line WL (see FIG. 12) of the gate stacked structure 3210.

In the semiconductor chip 2200 or the semiconductor device according to an embodiment, the first metal layer M1 that is located above the second transistor 222b and transmits a high voltage does not overlap another neighboring second transistor 222b. Accordingly, while reducing the size of the low-voltage first transistor 222a and maintaining high level of integration, an abnormal behavior of the high-voltage second transistor 222b can be prevented.

Each semiconductor chip 2200 includes a through wiring 3245 that is electrically connected to the peripheral wiring 3110 of the first structure 3100 and extends into the second structure 3200. The through wiring 3245 penetrates the gate stacked structure 3210, and is further disposed outside the gate stacked structure 3210. Each semiconductor chip 2200 further includes an input/output connection wiring 3265 that is electrically connected to the peripheral wiring 3110 of the first structure 3100 and extends into the second structure 3200 and the input/output pad 2210 electrically connected to the input/output connection wiring 3265.

In an embodiment, a plurality of semiconductor chips 2200 in the semiconductor package 2003 are electrically connected to each other by the connection structure 2400 in the form of a bonding wire. In an embodiment, a plurality of semiconductor chips 2200 or a plurality of portions that configure the semiconductor chips 2200 are electrically connected by a connection structure that includes a through electrode.

Referring to FIG. 15, in an embodiment, each of the semiconductor chips 2200a of a semiconductor package 2003A includes a semiconductor substrate 4010, a first structure 4100 disposed on the semiconductor substrate 4010, and a second structure 4200 bonded to the first structure 4100 by a wafer bonding method.

The first structure 4100 includes a peripheral circuit area that includes a peripheral wiring 4110 and a first bonding structure 4150. The second structure 4200 includes a common source line 4205, a gate stacked structure 4210 disposed between the common source line 4205 and the first structure 4100, a channel structure 4220 and a separation structure 4230 that penetrate the gate stacked structure 4210, and a second bonding structure 4250 that is electrically connected to the channel structure 4220 and the word line WL (see FIG. 12, hereinafter the same) of the gate stacked structure 4210. For example, the second junction structure 4250 is electrically connected to the channel structure 4220 and the word line WL, through a bit line 4240 that is electrically connected to the channel structure 4220 and a gate connection wiring that is electrically connected to the word line WL. The first bonding structure 4150 of the first structure 4100 and the second bonding structure 4250 of the second structure 4200 are bonded while being in contact with each other. Bonded portions of the first bonding structure 4150 and the second bonding structure 4250 are made of, for example, copper (Cu).

In the semiconductor chip 2200 or the semiconductor device according to embodiment, the first metal layer M1 that is located above the second transistor 222b and transmits a high voltage does not overlap another neighboring second transistor 222b. Accordingly, while reducing the size of the low-voltage first transistor 222a and maintaining a high level of integration, abnormal behavior of the high-voltage second transistor 222b can be prevented.

Each of the semiconductor chips 2200a further includes the input/output pad 2210 and an input/output connection wiring 4265 disposed under the input/output pad 2210. The input/output connection wiring 4265 is electrically connected to a portion of the second bonding structure 4250.

In an embodiment, a plurality of semiconductor chips 2200a in the semiconductor package 2003A are electrically connected to each other by the connection structure 2400 in the form of a bonding wire. In an embodiment, a plurality of semiconductor chips 2200 or a plurality of portions that configure the semiconductor chips 2200 are electrically connected by a connection structure that includes a through electrode.

Although embodiments of the present disclosure have been described in detail above, the scope of embodiments of the present disclosure are not necessarily limited thereto, and are intended to cover various modifications and equivalent arrangements included within the spirit and scope of the appended claims.

### DESCRIPTION OF SYMBOLS

222a: first transistor
222b: second transistor
M1: first metal layer
M2: second metal layer
210: first substrate
212: device isolation portion
A1: first transistor region
A2: second transistor region

What is claimed is:

1. A semiconductor device, comprising:
a semiconductor substrate that includes a first transistor region and a second transistor region;
a plurality of transistors that include a first transistor located in the first transistor region and a second transistor located in the second transistor region and that has a greater operating voltage than the first transistor; and
a first metal layer disposed on the first transistor and the second transistor,
wherein the first metal layer overlaps the second transistor and does not overlap a neighboring second transistor, and
wherein the first metal layer that overlaps the first transistor includes a wire that overlaps a neighboring first transistor.

2. The semiconductor device of claim 1, further comprising a second metal layer disposed on the first metal layer,
wherein the second metal layer overlaps the second transistor and includes a wire that overlaps another neighboring second transistor.

3. The semiconductor device of claim 1, further comprising a second metal layer disposed on the first metal layer,
wherein the second metal layer overlaps the second transistor and does not overlap a neighboring second transistor.

4. The semiconductor device of claim 3, further comprising a third metal layer disposed on the second metal layer,
wherein the third metal layer overlaps the second transistor and includes a wire that overlaps a neighboring second transistor.

5. The semiconductor device of claim 2, wherein:
the second transistor includes an active region and a gate electrode; and
a distance between the gate electrode and the second metal layer located closest to the gate electrode in a plan view is shorter than a distance between the gate electrode and the first metal layer located closest to the gate electrode in a plan view.

6. The semiconductor device of claim 1, further comprising a first via that connects the second transistor and the first metal layer,
wherein a distance between an edge of the first via and an edge of the first metal layer is less than 300 nm.

7. The semiconductor device of claim 1, further comprising a second metal layer disposed on the first metal layer,
wherein an area of the first metal layer that overlaps the second transistor in a plan view is smaller than an area of the second metal layer that overlaps the second transistor in a plan view.

8. The semiconductor device of claim 1, wherein a distance between the first metal layer and a gate electrode of the first transistor is shorter than the distance between the first metal layer and the gate electrode of the second transistor.

9. The semiconductor device of claim 1, wherein:
the second transistor includes an active region, and
the first metal layer that overlaps the second transistor does not extend across the active region of the second transistor.

10. A semiconductor device, comprising:
a semiconductor substrate that includes a first transistor region and a second transistor region;
a plurality of transistors that include a first transistor located in the first transistor region and a second transistor located in the second transistor region and that has a greater operating voltage than the first transistor;
a first metal layer disposed on the second transistor; and
a second metal layer disposed on the first metal layer,
wherein the first metal layer overlaps the second transistor and does not overlap a neighboring second transistor, and
wherein the second metal layer overlaps the second transistor and includes a wire that overlaps a neighboring second transistor.

11. The semiconductor device of claim 10, wherein an area of the first metal layer that overlaps the second transistor in a plan view is smaller than an area of the second metal layer that overlaps the second transistor in a plan view.

12. The semiconductor device of claim 10, further comprising a first via that connects the second transistor and the first metal layer,
wherein a distance between an edge of the first via and an edge of the first metal layer is less than 300 nm.

13. The semiconductor device of claim 10, wherein:
the second transistor includes an active region and a gate electrode, and
a distance between the gate electrode and the second metal layer located closest to the gate electrode is shorter than the distance between the gate electrode and the first metal layer located closest to the gate electrode.

14. The semiconductor device of claim 10, wherein:
the second transistor includes an active region; and
the first metal layer overlapping the second transistor is not located across the active region of the second transistor.

15. The semiconductor device of claim 10, further comprising a first metal layer located on the first transistor,
wherein the first metal layer that overlaps the first transistor includes a wire that overlaps a neighboring first transistor.

16. The semiconductor device of claim 15, wherein a distance between the first metal layer and a gate electrode of the first transistor is shorter than the distance between the first metal layer and the gate electrode of the second transistor.

17. An electronic system, comprising:
a main substrate;
a semiconductor device disposed on the main substrate; and
a controller electrically connected to the semiconductor device on the main substrate,
wherein the semiconductor device comprises:
a semiconductor substrate that includes a first transistor region and a second transistor region;
a plurality of transistors that include a first transistor located in the first transistor region and a second transistor located in the second transistor region and that has a greater operating voltage than the first transistor; and
a first metal layer disposed on the first transistor and the second transistor,
wherein the first metal layer overlaps the second transistor and does not overlap a neighboring second transistor, and
wherein the first metal layer overlaps the first transistor and includes a wire that overlaps a neighboring first transistor.

18. The electronic system of claim 17, further comprising a second metal layer disposed on the first metal layer,
wherein the second metal layer overlaps the second transistor and includes a wire that overlaps a neighboring second transistor.

19. The electronic system of claim 17, further comprising a first via that connects the second transistor and the first metal layer,
wherein a distance between an edge of the first via and an edge of the first metal layer is less than 300 nm.

20. The electronic system of claim 17, wherein:
the second transistor includes an active region; and
the first metal layer that overlaps the second transistor does not extend across the active region of the second transistor.
